(19) United States
(12) Patent Application Publication
(10) Pub. No.: US 2010/0038615 A1
(43) Pub. Date: Feb. 18, 2010

(54) NONVOLATILE STORAGE DEVICE

(76) Inventor: Takashi Nakagawa, Tokyo (JP)

Correspondence Address: Mr. Jackson Chen, 6535 N. STATE HWY 161, IRVING, TX, 75039, US

(21) Appl. No.: 12/514,771

(22) PCT Filed: Oct. 19, 2007
(86) PCT No.: PCT/JP2007/070464

§ 371 Date: May 13, 2009

(30) Foreign Application Priority Data
Nov. 22, 2006 (JP) 2006-315614

(51) Int. Cl. H01L 45/00

(52) U.S. Cl. 257/2; 257/E45.003

(57) ABSTRACT

An element structure for a resistance variable type nonvolatile storage device is provided in which enables a reduction in variation in operating voltage and in a leakage current in an off state of an element. The nonvolatile storage device is characterized by including a lower electrode, an upper electrode, and a laminated structure in which at least one amorphous insulating layer and at least one resistance variation layer are laminated between the lower electrode and the upper electrode.

### TECHNICAL FIELD

The present invention relates to a nonvolatile storage device in which the resistance of a resistance variation layer changes between at least two values and in which the change in resistance value is stored as information.

### BACKGROUND ART

In recent years, nonvolatile storage devices have been actively developed in which stored data does not disappear even when an external power source is turned off. As the nonvolatile storage devices, which now dominate relevant markets, flash memories, MONOSs (Metal Oxide Nitride Oxide Semiconductors), FeRAMs (ferroelectric memories), MRAMs (magnetic storage elements) have been proposed.

However, with miniaturization of memory elements making up each memory cell, ensuring the characteristics of the nonvolatile storage devices as storage elements has been difficult. For example, for the flash memory, a reduction in the thickness of a silicon oxide film between a floating gate (FG) portion and a semiconductor substrate may disadvantageously affect the charge holding capability of the memory. That is, when FN tunnel implantation is performed on a thin silicon oxide film of thickness at most 10 nm, a leakage current in a low electric field region called SILC (Stress Induced Leakage Current) may be generated. Then, charges accumulated in the FG may be lost through this leakage path.

Thus, in connection with the reduced thickness of the tunnel oxide film in the FG flash memory, the lower limit of the thickness needs to set to 8 nm in order to prevent a possible SILC to allow the charge holding capability to be maintained. As described above, for the FG flash memory, achieving both a reduction in operating voltage based on miniaturization and maintenance of the charge holding capability is difficult. Furthermore, also for the nonvolatile storage devices such as the MONOS, FeRAM, and MRAM as the FG flash memory, the miniaturization may reduce the amount of charges that can be held as information, resulting in degrading storage capacity.

Thus, a resistance variable type nonvolatile storage device including a resistance variation layer sandwiched between electrodes has been developed, as a nonvolatile storage device suitable for the miniaturization. This nonvolatile storage device is characterized in that the electric resistance of the resistance variation layer, made up of metal oxide or the like, is switched between at least two types of values by a certain electric stimulus so that the resistance value can be stored as information.

For the conventional storage device in which charges are accumulated in capacitors, the miniaturization has reduced the amount of accumulated charges and thus signal voltages. This has degraded the storage capacity. In contrast, the nonvolatile storage device utilizing the resistance variation layer is characterized in that it is suitable for the miniaturization because even with the miniaturization, the electric resistance generally remains unchanged and has a finite value.

Nonvolatile storage devices using Ni oxide as a resistance variation layer is proposed in Japanese Patent Laid-Open No. 2006-2108882, APPLIED PHYSICS LETTERS, 2006, 88, p. 202102-1 to 202102-3, and APPLIED PHYSICS LETTERS, 2005, 86, p. 093509-1 to 093509-3. Furthermore, these documents describe that a current path called a filament is formed in the Ni oxide and the resistance of the resistance variation layer varies depending on how the current path is joined to an upper electrode and a lower electrode.

### DISCLOSURE OF THE INVENTION

However, the following problems relating to the safety of the device have been found in the related art in Japanese Patent Laid-Open No. 2006-2108882, APPLIED PHYSICS LETTERS, 2006, 88, p. 202102-1 to 202102-3, and APPLIED PHYSICS LETTERS, 2005, 86, p. 093509-1 to 093509-3.

(1) First, in the structure in which the resistance variation layer is sandwiched between the electrodes described in Japanese Patent Laid-Open No. 2006-2108882, APPLIED PHYSICS LETTERS, 2006, 88, p. 202102-1 to 202102-3, and APPLIED PHYSICS LETTERS, 2005, 86, p. 093509-1 to 093509-3, the problem occurs in which a voltage threshold changing the resistance disadvantageously varies. It is considered that the threshold voltage becomes unstable because during repeated operation of the device, a new filament is formed in the resistance variation layer or an already formed filament disappears, resulting in preventing a stable filament from being formed in the resistance variation layer.

(2) Second, the resistance variation layer of the Ni oxide described in APPLIED PHYSICS LETTERS, 2005, 86, p. 093509-1 to 093509-3, has a polycrystalline structure. In this case, even when the storage device is off, that is, even when the filament in the resistance variation layer is disconnected between the electrodes, a leakage current may result from a grain boundary. Thus, the leakage current may preclude a pre-stored resistance value from being maintained or increase power consumption.

The present invention has been made to solve these problems. An object of the present invention is to inhibit a change in the number of current paths caused by the filament formed in the resistance variation layer, thus suppressing a possible variation in operating voltage or threshold voltage. Another object of the present invention is to inhibit a leakage current induced by the grain boundary to prevent a possible change in the resistance value of the resistance variation layer while the nonvolatile storage device is off, thus allowing information to be stably stored and preventing an increase in power consumption.

To solve the above described problems, the present invention is characterized by comprising the following configuration.

1. A nonvolatile storage device, comprising:

a lower electrode;

an upper electrode; and

a laminated structure in which at least one amorphous insulating layer and at least one resistance variation layer are laminated between the lower electrode and the upper electrode.

2. The nonvolatile storage device according to 1,

wherein the insulating layer is composed of a material having a lower dielectric constant than a material making up the resistance variation layer.

3. The nonvolatile storage device according to 1 or 2,

wherein the insulating layer contains an oxide, a nitride, or an oxynitride containing at least one element of Al and Si.

4. The nonvolatile storage device according to 1 or 2,

wherein the resistance variation layer is a crystalline layer containing at least an element contained in the insulating layer.

5. The nonvolatile storage device according to 1, 2, or 4,

wherein the resistance variation layer contains an oxide containing at least one type of element selected from a group consisting of Ni, V, Zn, Nb, Ti, W, and Co.

6. The nonvolatile storage device according to 1, 2, 4, or 5,

wherein the resistance variation layer contains crystalline nickel oxide, and

the insulating layer contains amorphous nickel oxide.

7. The nonvolatile storage device according to any one of 1 to 6,

wherein the lower electrode and the upper electrode contains at least one type of substance selected from a group consisting of Pt, Ru, RuO₂, Ir, Ti, TiN, and WN.

In the nonvolatile storage device according to the present invention, in a part of the resistance variation layer located on a region in which current flows as a result of dielectric breakdown of the amorphous insulating layer, a current path corresponding to a filament is formed along the region. Thus, during repeated operation of the nonvolatile storage device, formation of a new filament can be prevented, thus allowing a stable filament to be induced. Consequently, held resistance characteristics can be stabilized. As a result, the nonvolatile storage device exhibits stable storage holding characteristics.

Furthermore, by making the resistance variation layer being a crystalline layer, a leakage current induced by the grain boundary can be inhibited, thus preventing a possible change in the resistance value of the resistance variation layer while the nonvolatile storage device is off. As a result, information can be stably stored, and a possible increase in power consumption can be prevented.

### BRIEF DESCRIPTION OF THE DRAWINGS

FIG. 1 is a sectional view showing an example of a nonvolatile storage device according to the present invention;

FIG. 2 is a diagram illustrating functions of a conventional nonvolatile storage device and the nonvolatile storage device according to the present invention;

FIG. 3 is a sectional view showing an example of the nonvolatile storage device according to the present invention;

FIG. 4 is a sectional view showing an example of the nonvolatile storage device according to the present invention;

FIG. 5 is a sectional view showing an example of the nonvolatile storage device according to the present invention;

FIG. 6 is a sectional view showing a part of a manufacturing process for an example of the nonvolatile storage device according to the present invention;

FIG. 7 is a sectional view showing a part of the manufacturing process for the example of the nonvolatile storage device according to the present invention;

FIG. 8 is a sectional view showing a part of the manufacturing process for the example of the nonvolatile storage device according to the present invention;

FIG. 9 is a sectional view showing a part of the manufacturing process for the example of the nonvolatile storage device according to the present invention; and

FIG. 10 is a diagram showing the characteristics of a resistance variation layer according to the present invention.

### DESCRIPTION OF SYMBOLS

The symbols have the following meanings; 1: Silicon substrate, 2: Insulating film, 3: Lower electrode, 4: Interlayer insulating film, 5: Resistance variation layer, 6: Amorphous insulating layer, 7: Upper electrode, 8: Lower electrode, 9: Amorphous insulating layer, 10: Resistance variation layer, 11: Upper electrode, 12: Lower electrode, 13: Amorphous insulating layer, 14: Resistance variation layer, 15: Amorphous insulating layer, 16: Upper electrode, 17: Lower electrode, 18: Resistance variation layer, 19: Amorphous insulating layer, 20: Resistance variation layer, 21: Upper electrode, 22: Silicon substrate, 23: Silicon oxide film, 24: Titanium, 25: Titanium nitride, 26: Titanium, 27: Ruthenium, 28: Interlayer insulating film, 29: Resistance variation layer, 30: Amorphous insulating layer, 31: Upper electrode, 35: Current path via grain boundary, 36: Current path corresponding to filament, 37: Current path formed by dielectric breakdown, 38: Current path corresponding to filament, 39: Current path via grain boundary,

### BEST MODE FOR CARRYING OUT THE INVENTION

### (Nonvolatile Storage Device)

A nonvolatile storage device according to the present invention will be described below based on an exemplary embodiment.

The nonvolatile storage device according to the present invention includes a lower electrode, an upper electrode, and a laminated structure sandwiched between the lower electrode and the upper electrode. The laminated structure includes at least one insulating layer and at least one resistance variation layer. Here, the “resistance variation layer” refers to a layer the resistance of which can be varied between at least two types of values by applying a predetermined voltage hysteresis to the layer. If the resistance variation layer is composed of an insulating material, the resistance variation layer is distinguished from the insulating layer depending on whether or not the resistance of the layer can be varied between at least two types of values.

Furthermore, the “insulating layer” refers to an insulating amorphous layer which can be dielectrically broken down by applying a predetermined voltage to the layer and which does not have a plurality of resistance values (which are obtained while no dielectric breakdown is occurring) unlike in the case of the resistance variation layer. Whether or not the insulating layer is amorphous can be determined by using a TEM (Transmissive Electron Microscope) to obtain an electron diffracted image. That is, when the layer is amorphous, a clear electron diffracted image cannot be obtained with the TEM.

According to the present invention, an insulating layer of an amorphous structure which has no resistance variable function is formed adjacent to the resistance variation layer. Thus, in a part of the resistance variation layer located on a region in which current flows as a result of dielectric breakdown of the amorphous insulating layer, a current path corresponding to a filament is formed along the region. Thus, a stable filament can be induced in the resistance variation layer. Consequently, variation in the operating voltage of the nonvolatile storage device can be inhibited to allow information to be stably stored. Moreover, since the resistance variation layer becomes amorphous, a possible leakage current induced by a grain boundary can be prevented. This reduces the leakage current generated while the nonvolatile storage device is off, resulting in enabling the information storage device to be stabilized. Furthermore, an increase in power consumption can be prevented.

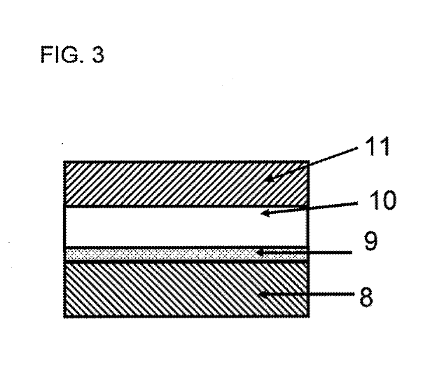

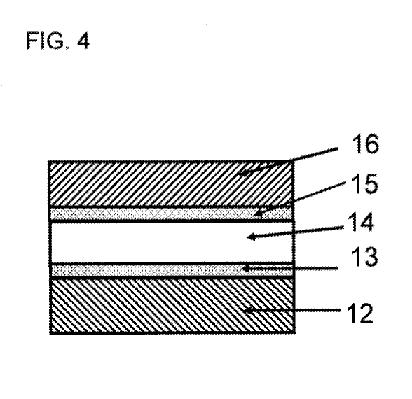

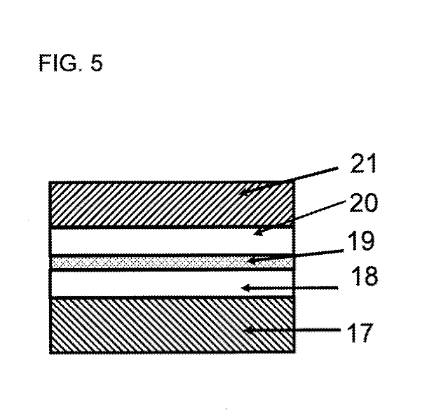

The numbers of insulating layers and resistance variation layers are not particularly limited provided that each of the layers is at least one. The condition in which the insulating layer and the resistance variation layer are laminated is also not particularly limited provided that the at least one resistance variation layer is adjacent to the at least one insulating layer. Furthermore, in the laminated structure, the lower electrode-side layer may be either the resistance variation layer or the insulating layer. The upper electrode-side layer may be either the resistance variation layer or the insulating layer. For example, as shown in FIG. 3, the laminated structure of the nonvolatile storage device according to the present invention may be such that a lower electrode 8, an insulating layer 9, a resistance variation layer 10, and an upper electrode 11 are laminated. Alternatively, as shown in FIG. 4, the laminated structure of the nonvolatile storage device according to the present invention may be such that a lower electrode 12, an insulating layer 13, a resistance variation layer 14, an insulating layer 15, and an upper electrode 16 are laminated. Alternatively, as shown in FIG. 5, the laminated structure of the nonvolatile storage device according to the present invention may be such that a lower electrode 17, a resistance variation layer 18, an insulating layer 19, a resistance variation layer 20, and an upper electrode 21 are laminated.

In the laminated structure, for example, an insulating layer, a resistance variation layer, and another insulating layer may be laminated, that is, the resistance variation layer may be sandwiched between the insulating layers. Alternatively, a resistance variation layer, an insulating layer, and another resistance variation layer may be laminated, that is, the insulating layer may be sandwiched between the resistance variation layers. Furthermore, the laminated structure including an insulating layer and a resistance variation layer with film thicknesses appropriate to allow the insulating layer to be dielectrically broken down by application of a predetermined voltage has only to be present in at least a part of the region between the upper and lower electrodes, and need not be present in all of the region between the upper and lower electrodes. For example, in certain structures, the distance between the upper and lower electrodes may vary depending on the position in the device. Even in this case, the insulating layer and the resistance variation layer may have such thicknesses and sectional areas as allows the insulating layer to be dielectrically broken down by means of the applied voltage, while allowing a filament to be formed in the resistance variation layer, in at least a part of the region between the upper and lower electrodes. Typically, dielectric breakdown can be more easily induced in regions in which the insulating layer is thinner. Thus, the insulating layer and the resistance variation layer may only have thicknesses appropriate to induce dielectric breakdown between the upper and lower electrodes.

When the laminated structure is present in a very small part of the region between the upper and lower electrodes, and a conductive region is present in the vicinity of the resistance variation layer, then during voltage application, current may flow through the resistance variation layer via the conductive region instead of flowing through the resistance variation layer via the insulating layer. Thus, if the laminated structure is formed in a part of the region between the upper and lower electrodes, the insulating layer and the resistance variation layer need to have sectional areas appropriate to allow current to flow only via the insulating layer. Furthermore, it is necessary to prevent current from flowing through the resistance variation layer via the conductive region. The laminated structure of the resistance variation layer and the insulating layer may be planar or may be bent in the middle thereof provided that the structure is sandwiched between the upper and lower electrodes.

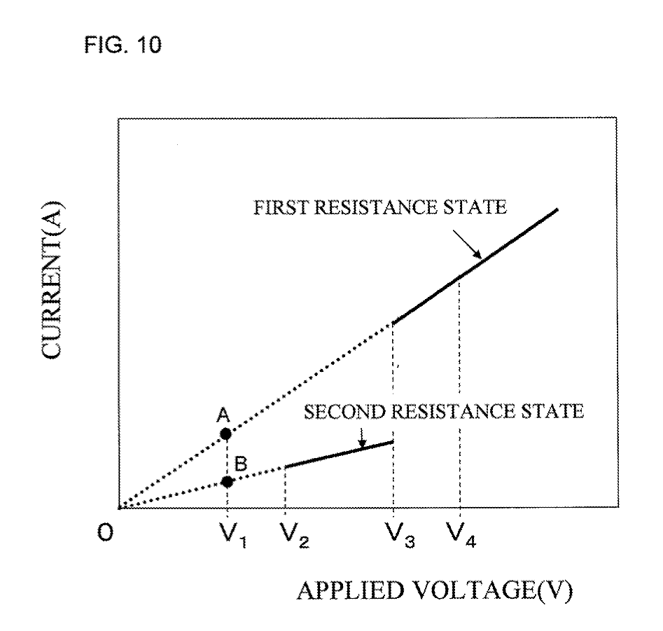

The thickness of the insulating layer (if the insulating layer is made up of a plurality of layers, the thickness of each of the layers) needs to be such that dielectric breakdown occurs at least at a voltage V₁ described below with reference to FIG. 10. The thickness is preferably 1 to 10 nm, more preferably 3 to 10 nm, most preferably 5 to 10 nm.

The insulating layer is preferably composed of a material with a lower dielectric constant than a material making up the resistance variation layer. When the insulating layer is composed of a material with a lower dielectric constant than the material making up the resistance variation layer, electric fields can be effectively applied even to the resistance variation layer.

The insulating layer preferably contains, in at least a part thereof, an oxide containing at least one of the two elements Al and Si, a nitride containing at least one of the two elements Al and Si, or an oxynitride containing at least one of the two elements Al and Si. Such an oxide, a nitride, or an oxynitride facilitates the control of the thickness, dielectric breakdown characteristics (the voltage at which the insulating layer is dielectrically broken down), and the like. Such an oxide, a nitride, or an oxynitride may be, for example, Al₂O₃ or SiO₂. Furthermore, the oxide, nitride, or oxynitride can be formed into a continuous insulating layer by varying only deposition conditions. Thus, these materials enable a relevant process to be simplified, allowing a reduction in costs. Additionally, the materials serve to improve the deposition and adhesion of the resistance variation layer and the insulating layer.

The resistance variation layer preferably contains an oxide containing at least one type of element selected from a group consisting of Ni, V, Zn, Nb, Ti, W, and Co. Examples of the oxide include nickel oxide (NiO), vanadium oxide (V₂O₅), zinc oxide (ZnO), niobium oxide (Nb₂O₅), titanium oxide (TiO₂), tungsten oxide (WO₃), and cobalt oxide (CoO). The resistance variation layer containing such an element can stably exhibit at least two types of resistance values.

Among these oxides, nickel oxide (NiO) is preferably used. The nickel oxide (NiO) exhibits at least two types of resistance values. Furthermore, the rate of resistance change between the resistance values of the nickel oxide is so high that information can be effectively stored. Moreover, the nickel oxide is very compatible with the existing process. Thus, the nickel oxide can be very excellently deposited using the existing process.

The resistance variation layer is preferably a crystalline layer containing the same element as that contained in the insulating layer. Here, the resistance variation layer and the insulating layer have only to contain the same element in at least a part thereof. The resistance variation layer and the insulating layer may be composed of different materials. Alternatively, the resistance variation layer and the insulating layer may be composed of the same element, but the composition of the element in the resistance variation layer may be different from that of the element in the insulating layer. Thus, by containing the same element in the resistance variation layer and the insulating layer, the adhesion and deposition of these layers can be improved.

Furthermore, preferably, the resistance variation layer contains crystalline nickel oxide, and the insulating layer contains amorphous nickel oxide. When the crystalline nickel oxide is used in the resistance variation layer, the resistance variation layer exhibits at least two types of resistance values, and the rate of resistance change between the resistance values is high. Thus, information can be effectively stored. When the amorphous nickel oxide is used in the insulating layer, the control of the dielectric breakdown is facilitated. Moreover, the nickel oxide is very compatible with the existing process. Consequently, the nickel oxide can be very excellently deposited using the existing process.

Each of the lower and upper electrodes preferably contains at least one type of substance selected from a group consisting of Pt, Ru, RuO₂, Ir, Ti, TiN, and WN. These electrode materials are unlikely to be oxidized, thus inhibiting an increase in resistance caused by the oxidation of the electrode material. The lower and upper electrodes may be composed of a plurality of layers made up of different materials.

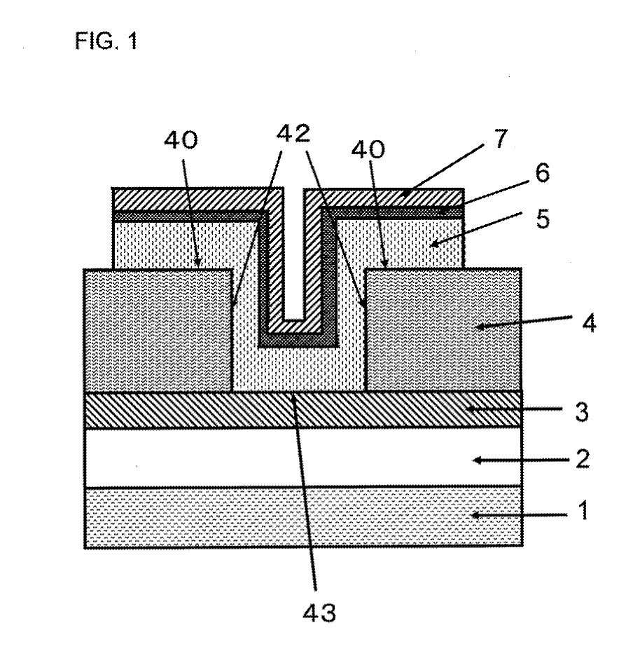

FIG. 1 shows an example of a nonvolatile storage device according to the present invention. In the nonvolatile storage device in FIG. 1, a silicon substrate 1, an insulating layer 2, and a lower electrode layer 3 are laminated. An interlayer insulating film 4 is formed on the lower electrode layer 3. An opening is formed in the interlayer insulating film 4. A resistance variation layer 5, an insulating layer 6, and an upper electrode 7 are laminated so as to extend from a top surface 40 of the interlayer insulating film 4, along a side surface 42 and a bottom surface 43 of the opening and then along the side surface 42 again, and back to the top surface 40 of the interlayer insulating film 4. Thus, the resistance variation layer 5, the insulating layer 6, and the upper electrode 7 may be bent in the middle.

### (Functions and Effects)

First, the resistance variation layer will be described. As shown in FIG. 10, the resistance variation layer exhibits two types of resistance values, that is, a voltage-current characteristic indicated by a first resistance state and a voltage-current characteristic indicated by a second resistance state. That is, when the voltage applied to the resistance variation layer is between V₂ and V₃, a small current flows through the resistance variation layer (a second resistance state with a large resistance value). On the other hand, when the voltage applied to the resistance variation layer exceeds V₃, a large current flows through the resistance variation layer (a first resistance state with a small resistance value).

Here, when the voltage applied to the resistance variation layer is changed from at least V₂ to a value smaller than V₂ (for example, V₁), the resistance state observed when the applied voltage is V₁ varies depending on whether the voltage is reduced from the first resistance state to V₁ or from the second resistance state to V₁. As shown in FIG. 10, when the voltage is reduced from the first resistance state (V>V₃) to V₁, the first resistance state remains unchanged, with the current value at the voltage V₁ increased (the resistance value reduced) (point A). On the other hand, when the voltage is reduced from the second resistance state (V₂≦V≦V₃) to V₁, the second resistance state remains unchanged, with the current value at the voltage V₁ reduced (the resistance value increased) (point A).

As described below, the first resistance state is expected to be such that a filament connecting the interior of the resistance variation layer to the opposite sides in the thickness direction thereof is formed to reduce the resistance value. Furthermore, the second resistance state is expected to be such that the filament formed in the resistance variation layer is broken to increase the resistance value.

The resistance value is held even after the application of the voltage V₁ has been stopped. Thus, the held resistance value can be stored as information. For example, the information can be stored with the first and second resistance states defined as “0” and “1”, respectively. Furthermore, when the information is read, whether the information held in the resistance variation layer indicates the “0” state or the “1” state can be determined by measuring a current flowing when a voltage smaller than V₁ is applied to the resistance variation layer. Whether each of the first and second resistance states is defined as “1” or “0” can be optionally selected.

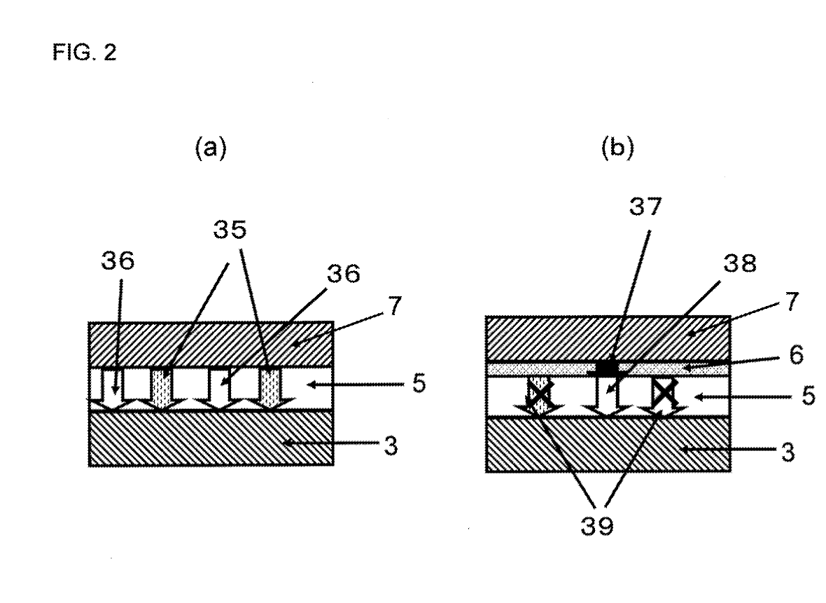

Now, mechanisms for the effects of inhibiting variation in operating voltage and reducing a leakage current in an off state according to the present invention will be described. FIG. 2 shows the characteristics of features of the nonvolatile storage device produced according to the present invention compared with those of a conventional example.

As shown in FIG. 2(a), in the conventional nonvolatile storage device, the resistance variation layer 5 and the upper electrode 7 are laminated in this order on the lower electrode 3. The conventional nonvolatile storage device includes two current paths for a switching operation. One of the current paths is a filament 36 formed in the resistance variation layer. The other is a current path 35 due to a grain boundary.

In the conventional nonvolatile storage device, in the off state, the current path 36, corresponding to the filament, is blocked, but the current path 35 via grain boundary, is present. This reduces the resistance. Thus, in the off state, the leakage current and thus the power consumption disadvantageously increase. Furthermore, during repeated operations, the filament 36 may be irregularly formed in any region to change the voltage-current characteristics indicating V₂, V₃, and the first and second resistance states in FIG. 10. As a result, device characteristics are expected to change, making stable storage of information difficult.

In contrast, in the nonvolatile storage device according to the present invention, the amorphous insulating layer 6 is formed between the resistance variation layer and the electrode as shown in FIG. 2(b). When a predetermined voltage is applied to the nonvolatile storage device, the insulating layer 6 is dielectrically broken down and a current 37 then flows from the dielectrically broken-down portion. The voltage at which the insulating layer is dielectrically broken down varies depending on the component and thickness of the insulating film. Thus, the voltage is set to a value at which the insulating layer can be dielectrically broken down.

A filament 38 is formed in a part of the resistance variation layer on the dielectrically broken-down portion in the insulating layer. That is, the current path 37 is formed in the dielectrically broken-down portion in the insulating layer, whereas a current path 39 via the grain boundary or the like is not formed in the other portions in the insulating layer. Thus, in the resistance variation layer, the filament 38 is formed only in the corresponding part located on the dielectrically broken-down portion of the insulating layer. In this manner, in the resistance variation layer, the filament 38 is constantly formed in the particular part (on the dielectrically broken-down portion of the insulating layer), and the current path 39 via the grain boundary or the like is not formed. Consequently, even during the repeated operation of the device, no new filament is formed in the resistance variation layer. As a result, the voltage-current characteristics indicating V₂, V₃, and the first and second resistance states in FIG. 10 as well as resistance characteristics remain unchanged. This enables information to be stably stored.

As described above, the effect of inhibiting variation in operating voltage according to the present invention is expected to result from the formation of the filament only in the part of the resistance variation layer which corresponds to the dielectrically broken-down region of the insulating layer. Furthermore, in the nonvolatile storage device according to the present invention, when the amorphous insulating layer is present between the amorphous resistance variation layer and the electrode, a possible leakage current via the grain boundary can be inhibited. This effectively enables a reduction in the leakage current from the storage device in the off state. Thus, the structure according to the present invention inhibits variation in the operating voltage of the nonvolatile storage device, resulting in enabling a reduction in the leakage current in the off state.

### (Method of Manufacturing a Nonvolatile Storage Device)

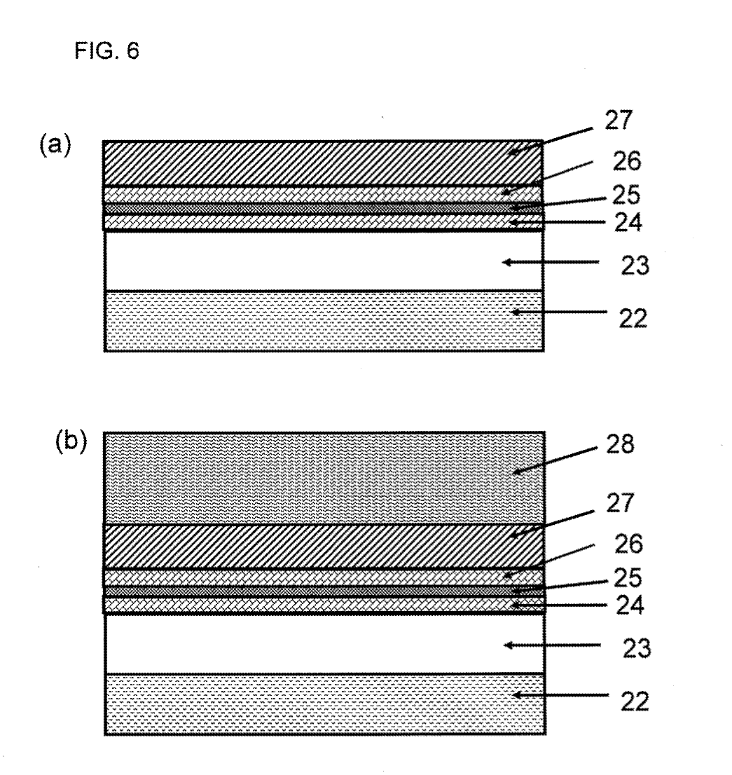

An example of a method of manufacturing a nonvolatile storage device according to the present invention will be described below with reference to FIGS. 6 to 9. First, a silicon oxide film 23 is formed on a silicon substrate 22 using a thermal oxidation method or a CVD method. Then, a lower electrode made up of titanium 24, titanium nitride 25, titanium 26, and ruthenium 27 is formed on the silicon oxide film 23 using a sputtering method or a CVD method (FIG. 6(a)). A material for the lower electrode is preferably selected from a group consisting of Pt, Ru, RuO₂, Ir, Ti, TiN, and WN in order to inhibit a possible increase in resistance caused by oxidation of an electrode material during a postprocess. Furthermore, to improve the adhesion between the silicon substrate and the electrode material, a plurality of layers are preferably laminated as the lower electrode. As the lower electrode, the laminated structure of Ti and TiN is preferably used.

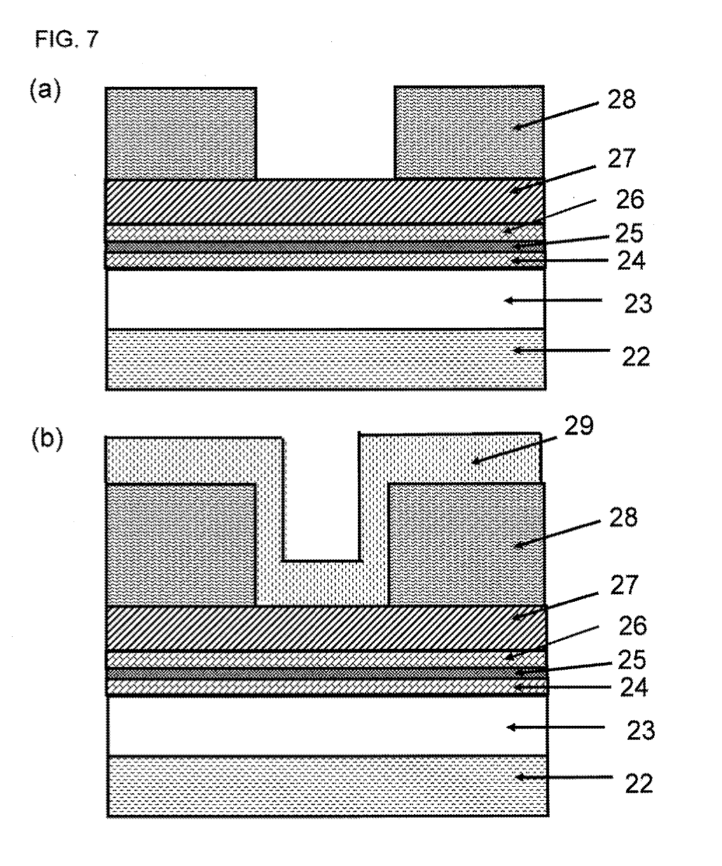

Then, an interlayer insulating film 28 is formed on the lower electrode 27 (FIG. 6(b)). An opening is subsequently formed in the interlayer insulating film 28 using photolithography and dry etching, or wet etching (FIG. 7(a)). A crystalline resistance variation layer 29 is then formed by a CVD method or a sputtering method so as to connect at least to the lower electrode (ruthenium 27) exposed in the opening (FIG. 7(b)). The crystalline resistance variation layer can be formed by varying the temperature of the substrate during execution of the sputtering method or the CVD method. For example, the crystalline substance (resistance variation layer) of oxide can be formed by the sputtering method involving introduction of oxygen. More specifically, an NiO layer (the resistance variation layer of the crystalline substance) can be formed by the CVD deposition using a nickel material and an oxygen material. The resistance variation layer 29 is preferably an oxide containing at least one type of element selected from a group consisting of Ni, V, Zn, Nb, Ti, W and Co.

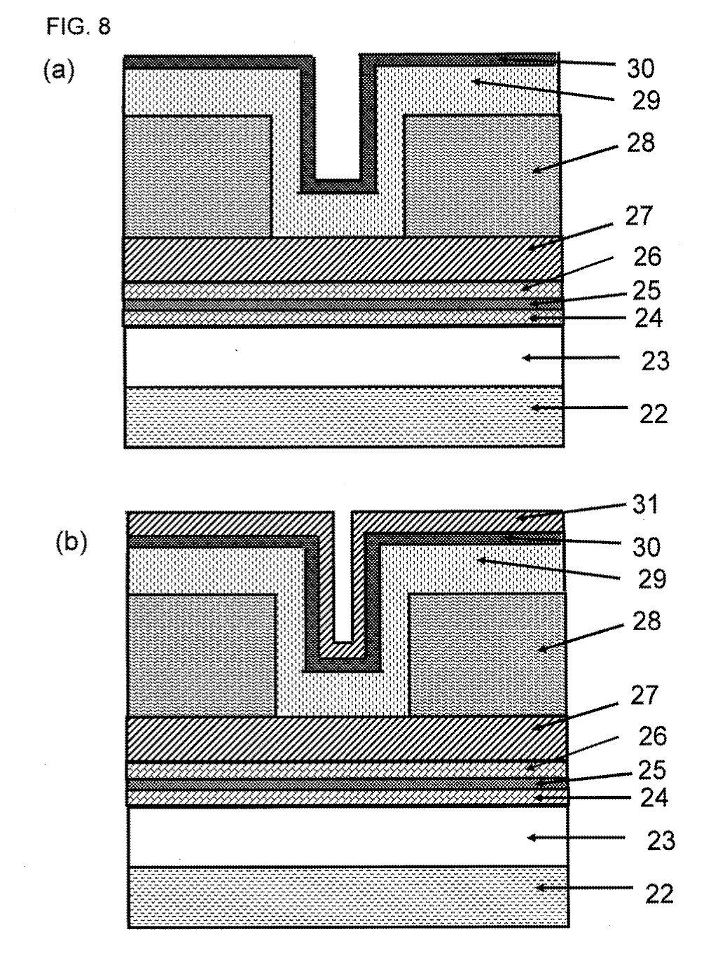

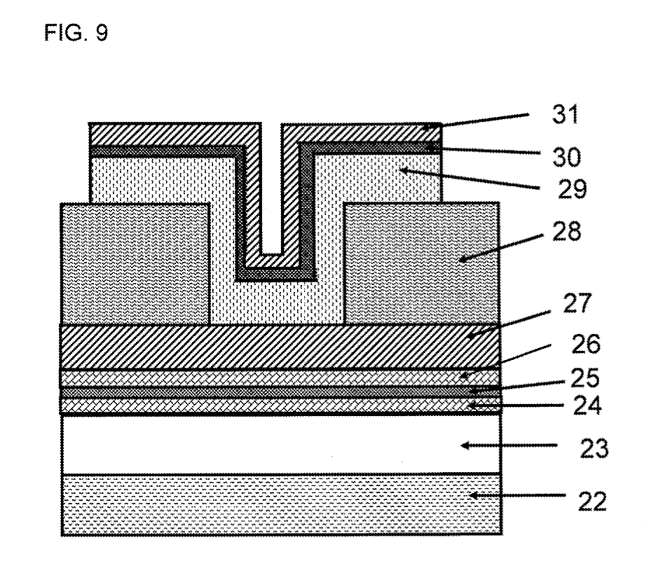

Then, an amorphous insulating layer 30 is formed on the resistance variation layer 29 by the CVD method, an ALD method, or the sputtering method (FIG. 8(a)). When any of these methods is used, the amorphous layer can be obtained by reducing the substrate temperature. For example, when Al₂O₃ is formed, the amorphous layer can be formed at a substrate temperature of at most 600° C. Then, an upper electrode 31 is deposited on the insulating layer 30 using the sputtering method or the CVD method (FIG. 8(b)). The electrode material for the upper electrode 31 is preferably at least one type of substance selected from a group consisting of Pt, Ru, RuO₂, Ir, Ti, TiN and WN in order to inhibit a possible increase in resistance caused by oxidation of an electrode material during a postprocess. Then, the upper electrode 31, the insulating layer 30, and the resistance variation layer 29 are subjected to photolithography and dry or wet etching to process the electrode. Such a structure as shown in FIG. 9 is thus obtained.

### Embodiment

FIGS. 6 to 9 are sectional views showing a process of producing a nonvolatile storage device according to the present invention. First, the silicon substrate 22 was prepared. The silicon oxide film 23 of film thickness 100 nm was then deposited on the silicon substrate 22 using the CVD method or the thermal oxidation method. Thereafter, the Ti layer 24, TiN layer 25, Ti layer 26 were deposited using the sputtering method. An Ru film of film thickness 100 nm was then deposited. Finally, the lower electrode 27 was formed (FIG. 6(a)).

Then, the silicon oxide film 28 of film thickness 200 nm was formed using the CVD method (FIG. 6(b)). A photo resist (not shown in the drawings) was deposited so as to cover the silicon oxide film 28. An opening was thereafter formed by photolithography and dry etching (FIG. 7(a)).

Then, the crystallized nickel oxide (resistance variation layer) 29 was deposited to a film thickness of 10 nm by the sputtering method (FIG. 7(b)). Here, the nickel oxide layer 29 may be formed by the CVD method.

Then, the amorphous aluminum oxide film (insulating layer) 30 of thickness 3 nm was deposited by a MOCVD (Metal Organic Chemical Vapor Deposition) method (FIG. 8(a)). At this time, Al(CH₃)₃ was used as an organic metal material, and H₂O was used as an oxidizer. Al(CH₃)₃ and H₂O were alternately fed onto the substrate heated to 300° C., to form aluminum oxide. Alternatively, ozone may be used as an oxidizer. Furthermore, by controlling the partial pressure of the introduced oxidizer, an ALD (Atomic Layer Deposition) method or a PVD (Physical Vapor Deposition) method such as sputtering may be used.

Then, Ru of film thickness 20 nm was formed as the upper electrode 31 by the sputtering method (FIG. 8(b)). The upper electrode 31, the insulating layer 30, the resistance variation layer 29 were thereafter processed by photolithography and dry etching to obtain a nonvolatile storage device configured as shown in FIG. 9.

The electrical characteristics of the thus produced nonvolatile storage device were evaluated. Then, the nonvolatile storage device according to the present invention was determined to enable a reduction in the leakage current in the off state compared to a nonvolatile storage device without an amorphous insulating layer. Furthermore, repeated operations were performed. Then, in the nonvolatile storage device without an amorphous insulating layer, a switching voltage varied as the number of repetitions increased. In contrast, in the nonvolatile storage device according to the present invention, it was confirmed that the switching voltage remained almost unchanged.

The present invention has been described with reference to the exemplary embodiment. However, the present invention is not limited to the above-described exemplary embodiment. Various changes that can be appreciated by those skilled in the art may be made to the configuration and details of the present invention in the technical scope of the present invention.

This application is based upon and claims the benefit of priority from Japanese patent application No. 2006-315614, filed on Nov. 22, 2006, the disclosure of which is incorporated herein in its entirely by reference.

1. A nonvolatile storage device, comprising:
a lower electrode;
an upper electrode; and
a laminated structure including at least one amorphous insulating layer and at least one resistance variation layer laminated between the lower electrode and the upper electrode.

2. The nonvolatile storage device according to claim 1,
wherein the insulating layer is composed of a material having a lower dielectric constant than a material making up the resistance variation layer.

3. The nonvolatile storage device according to claim 1,
wherein the insulating layer contains an oxide, a nitride, or an oxynitride containing at least one element of Al and Si.

4. The nonvolatile storage device according to claim 1,
wherein the resistance variation layer is a crystalline layer containing at least an element contained in the insulating layer.

5. The nonvolatile storage device according to claim 1,
wherein the resistance variation layer contains an oxide containing at least one type of element selected from a group consisting of Ni, V, Zn, Nb, Ti, W, and Co.

6. The nonvolatile storage device according to claim 1,
wherein the resistance variation layer contains crystalline nickel oxide, and
the insulating layer contains amorphous nickel oxide.

7. The nonvolatile storage device according to claim 1,
wherein the lower electrode and the upper electrode contains at least one type of substance selected from a group consisting of Pt, Ru, RuO₂, Ir, Ti, TiN, and WN.
